(19) United States
(12) Patent Application Publication
(10) Pub. No.: US 2015/0160279 A1
(43) Pub. Date: Jun. 11, 2015

(54) QUANTITATIVE CHARACTERIZATION OF NONLINEARITY AND MEMORY EFFECT IN NONLINEAR CIRCUITS

(71) Applicant: QUALCOMM Incorporated, San Diego, CA (US)

(72) Inventors: Hao Zhou, Sunnyvale, CA (US); Feipeng Wang, San Jose, CA (US); Haojen Cheng, Santa Clara, CA (US); Volodymyr Rakytyanskyy, San Jose, CA (US)

(21) Appl. No.: 14/564,071

(22) Filed: Dec. 8, 2014

Related U.S. Application Data
(60) Provisional application No. 61/913,907, filed on Dec. 9, 2013.

(51) Int. Cl. G01R 29/26; H03F 1/32

(52) U.S. Cl. CPC G01R 29/26; H03F 1/3247; H03F 2201/3224

(57) ABSTRACT

An input signal is transmitted to a component. A distortion associated with the component is determined based, at least in part, on an output signal generated by the component in response to the input signal. A distortion error measurement associated with the component is determined based, at least in part, on the distortion and the output signal generated by the component. A memory effect and the associated nonlinearity within the component are quantified based, at least in part, on the distortion error measurement.

### RELATED APPLICATIONS

This application claims the priority benefit of U.S. Provisional Patent Application No. 61/913,907 filed Dec. 9, 2013.

### BACKGROUND

Embodiments of the subject matter generally relate to the field of communication systems and, more particularly, to analysis of nonlinearity and memory effects of nonlinear systems based on amplitude modulation to amplitude modulation (“AM/AM”) and amplitude modulation to phase modulation (“AM/PM”) error estimations.

Conventional transmission circuitry allows digital information to be converted to analog signals and transmitted over a wireless or wired communication channel. Amplification components in transmission circuitry may amplify a source signal as part of a transmission via the communication channel. Nonlinear distortions in the amplification components may cause noise or transmission errors. This may cause the amplification components (e.g., a power amplifier) to lose a linear relationship between an input/source signal and an amplified output signal.

### SUMMARY

Various embodiments for quantifying memory effects in nonlinear systems are disclosed. In one embodiment, a device causes an input signal to be transmitted to a component. The device determines a distortion associated with the component based, at least in part, on an output signal generated by the component in response to the input signal. The device further determines a distortion error measurement associated with the component based, at least in part, on the distortion and the output signal generated by the component. The device further quantifies a memory effect associated with the component based, at least in part, on the distortion error measurement.

### BRIEF DESCRIPTION OF THE DRAWINGS

The present embodiments may be better understood, and numerous objects, features, and advantages made apparent to those skilled in the art by referencing the accompanying drawings.

FIG. 1 is a block diagram of a test environment;

FIG. 2 is a flow diagram illustrating example operations for error measurement in a power amplifier using a two-tone signal;

FIG. 3 is a block diagram of an embodiment of an electronic device including a mechanism for two-tone error estimation of a nonlinear component;

### DESCRIPTION OF EMBODIMENT(S)

The description that follows includes example systems, methods, techniques, and program code/instructions that embody techniques of the present subject matter. However, it is understood that the described embodiments may be practiced without these specific details. For example, although error measurement techniques described herein can be performed using a two-tone sinusoidal signal, embodiments are not so limited. In other embodiments, the error measurement techniques can be executed using a multi-tone signal (e.g., a three-tone signal) that has any suitable waveform type (e.g., a triangular waveform). In other instances, well-known instruction instances, protocols, structures, and techniques have not been shown in detail in order not to obfuscate the description.

Nonlinearity and memory effects are two main challenges to nonlinear system design, such as a power amplifier (PA) design, for a wideband wireless communication system. For example, a high-efficiency PA may operate in a nonlinear manner. Memory effects associated with a PA indicate that the output of the PA does not solely depend on the instantaneous input of the PA, but also depends on the history of the PA (e.g., previous inputs/outputs of the PA). Although nonlinearity and memory effects are common in a nonlinear system, these effects become more prominent and have a greater impact in a wideband wireless communication system. This is because the high power efficiency of the wideband wireless communication system may result in high nonlinearity; and the high data-rate of the wideband wireless communication system may result in a large memory effect. Existing techniques for quantifying the nonlinearity and memory effects analyze the intermodulation components of the PA. However, these techniques do not provide information about the link between the nonlinearity and memory effects and the resulting performance impact on the communication system. For example, even after using digital pre-distortion, it may be difficult to determine whether performance degradation (e.g., error vector measurement (EVM) degradation) was caused by the nonlinearity or the memory effect associated with the PA.

In some embodiments, the nonlinearity and memory effects of a nonlinear component (e.g., a power amplifier) can be quantified by using the two-tone test in combination with a distortion measurement technique (e.g., AM/AM (amplitude distortion) and AM/PM (phase distortion) error measurement techniques). Error measurements that are determined as a result of the distortion measurement technique can be used to quantify the characteristics of the PA (or PA linearization algorithm) to achieve a desired performance. Such a mechanism for evaluating the nonlinearity and memory effects of a nonlinear component can result in a high correlation between the distortion measurements and the communication system performance. For example, this mechanism can provide information about the correlation between the AM/AM and AM/PM errors and the EVM. This mechanism can also help validate the quality of the nonlinear system design, the performance of linearization algorithms, and the efficacy of pre-distortion correction factors.

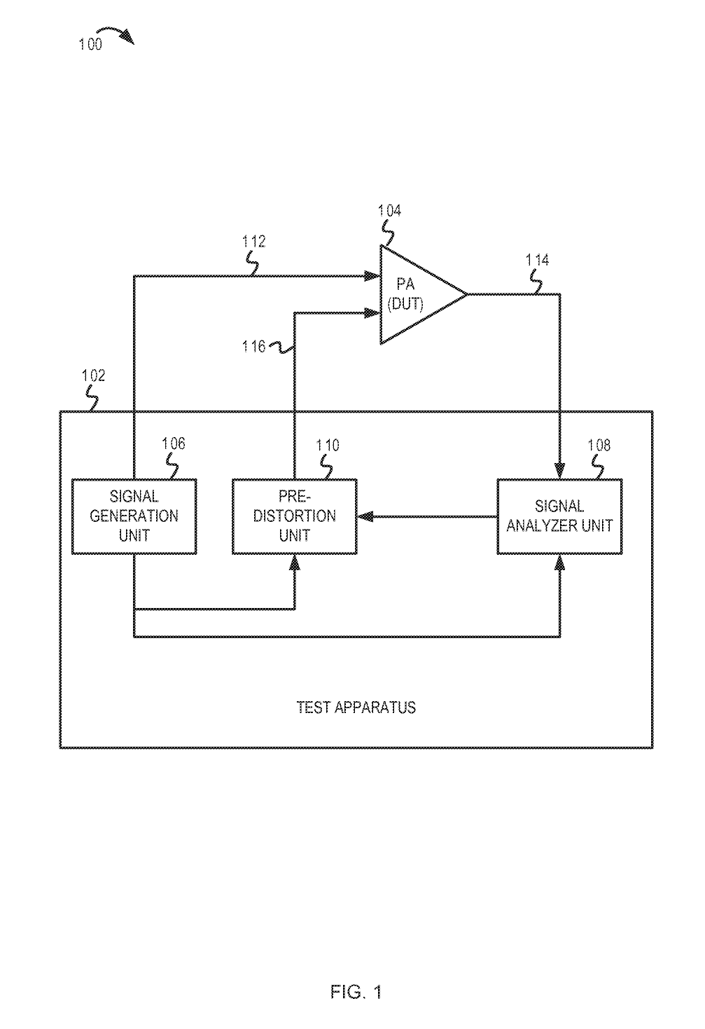

FIG. 1 is a block diagram of a test environment for error measurement in a nonlinear component in accordance with one embodiment. The test environment 100 includes a test apparatus 102 and a nonlinear component as the device under test (DUT), such as the PA 104. The test apparatus 102 includes a signal generation unit 106, a signal analyzer unit 108, and a pre-distortion unit 110. The device under test can be a nonlinear memory component or another suitable unit that exhibits nonlinearity and/or memory effects. In some embodiments, the power amplifier 104 may be deployed in various types of communication devices and systems, such as a cable television set-top box, a laptop computer, a tablet computer, a gaming console, a media player, a smart appliance, an access point, a mobile device, or another suitable electronic device. The PA 104 may receive an analog input signal scheduled for transmission and may amplify the analog input signal. The amplified signal may be transmitted via an antenna over a communication channel. In one example, the PA 104 may be included in a WLAN device (e.g., receive and amplify WLAN signals before transmission). However, in other embodiments, the PA 104 may be included in a network device that implements other suitable wired and/or wireless communication technologies (e.g., Bluetooth® technology, WiMAX technology, Ethernet, powerline communication (PLC), etc.). The PA 104 combines input signals from the signal generation unit 106 (the PA input signal 112) and the pre-distortion unit 110 (the pre-distortion correction factor input signal 116).

Two power amplifier characteristics are amplitude distortion (also referred to as “AM/AM”) and phase distortion (also referred to as “AM/PM”). The AM/AM power amplifier characteristics refer to the change in the output power gain (e.g., in dB) versus input power, relative to an amount of signal gain. The AM/PM power amplifier characteristics refer to the change in the output phase (e.g., in degrees) versus input power, relative to a change in signal conditions. For a system that does not exhibit memory effects (“memory-less system”), there is a one-to-one relationship between the AM/AM error value and the input power and also between the AM/PM error value and the input power. However, for a component or system that has memory effects (e.g., the PA 104), there may be multiple AM/AM and AM/PM error values associated with input power due to the PA memory and the previous signal values.

The test apparatus 102 can implement functionality to automatically evaluate the nonlinearity and memory effects of the PA 104. The signal generation unit 106 can generate a baseband signal that is represented as

$$sin ( 2 π \frac{{f}_{d}}{2} t ) .$$

The signal generation unit 106 can up-convert the baseband signal to yield a radio frequency (RF) two-tone signal, such that the tone spacing (or frequency spacing) is f_{d}. In some embodiments, the RF two-tone signal may be a combination signal that includes two synchronized signal components—a first signal component associated with a first frequency and a second signal component associated with a second, synchronized, frequency. A two-tone signal that includes synchronized signal components provides a clean sine-shaped RF envelope and constant carrier phase. Such two-tone signal facilitates the measurement of the nonlinearity associated with PA 104. As an example, the RF two-tone signal may be represented by Eq. 1.

x=sin(2πft)+sin((2π(f+f_{d})t) Eq. 1

In Eq. 1, x represents the two-tone signal provided to the input of the PA 104 (i.e., the PA input signal), f represents the first frequency associated with the first signal component, f_{d} represents the tone spacing or frequency spacing, and (f+f_{d}) represents the second frequency associated with the second signal component. The two signal components (or tones) that constitute the RF two-tone signal may be synchronized with each other. The RF two-tone signal may have an amplitude envelope that varies in accordance with the absolute value of that baseband signal

$$sin ( 2 π \frac{{f}_{d}}{2} t ) .$$

The synchronization two-tone signal may be a baseband signal which is a sine wave with four phases. It is noted that the two signal components in the two-tone signal may be synchronized such that the RF envelope of the two-tone signal has a clean trajectory for AM/AM and AM/PM measurement. The tone spacing between the two signal components can be swept across the desired frequency band for testing. The tone-strength can be swept across different power levels for testing. The signal generation unit 106 provides the RF two-tone signal to the PA 104. The signal analyzer unit 108 may use the RF two-tone signal to determine AM/AM and AM/PM error measurements for the PA 104, as will be further described below.

The test apparatus 102 executes the AM/AM and AM/PM error measurement technique by providing the RF two-tone signal to the PA 104. The signal analyzer unit 108 determines the signal at the output 114 of the PA (“measured PA output signal 114”). The signal analyzer unit 108 (or another suitable error measurement unit) may synchronize the measured PA output signal (y) 114 with the PA input signal (x) 112. The signal analyzer unit 108 may compare the measured PA output signal 114 with the PA input signal 112 to yield an AM/AM and AM/PM trajectory for the PA 104. The AM/AM and AM/PM trajectory represents the PA nonlinearity and memory effects.

Next, the test apparatus 102 can determine AM/AM and AM/PM error. In some implementations, the AM/AM and AM/PM error can be defined as the difference between the instantaneous AM/AM and AM/PM and the predicted AM/AM and AM/PM curves of a memory-less linear PA. The signal analyzer unit 108 can determine a predicted memory-less linear PA output signal, ŷ, by, for example, generating a first order curve fitting result, as represented by Eq. 2

ŷ=kx Eq. 2

The signal analyzer unit 108 can compare the AM/AM and AM/PM trajectory to the first order curve fitting result. As described above, x represents the two-tone RF input signal that is provided as an input to the PA 104. The PA input signal 112 and the measured PA output signal 114 (i.e., x and y) are used to determine a linear coefficient k (e.g., using linear regression or other suitable linear estimation techniques). The AM/AM and AM/PM error can then be determined using Eq. 3.

AM−AM AM−PM error=y−ŷ=y−kx Eq. 3

In other words, the difference between ŷ, which represents a predicted output signal for a linear PA with no memory effect, and y, which represents a measured PA output signal, can be attributed to the nonlinearity and memory effects associated with PA 104.

The AM/AM and AM/PM error can be analyzed to evaluate the nonlinearity and memory effects of the PA 104, and to determine how to compensate for the nonlinearity and memory effects. Using a two-tone synchronized signal can yield an AM/AM and AM/PM error that has lower interference/unwanted components in the frequency spectrum (e.g., a “clean” frequency spectrum) when compared to other forms of probing signals, such as a triangular envelope signal.

In some embodiments, the AM/AM and AM/PM error measurement techniques may be combined with other techniques, such as digital pre-distortion (DPD) techniques. Since PA 104 may cause nonlinear distortion to a signal that is scheduled for transmission, the pre-distortion unit 110 can adjust an input signal (provided to the PA 104) to prepare a pre-distorted signal that can compensate for the PA nonlinearity in the digital domain. The pre-distorted signal may have an inverse distortion as compared to the nonlinear distortion of the PA 104. The pre-distortion unit 110 can determine pre-distortion correction factors that allow the PA 104 to operate with high power-added efficiency (PAE) near saturation without significant signal distortion. In some embodiments, the pre-distortion unit 110 may apply pre-distortion correction factors to the PA input signal (e.g., the RF two-tone signal) to determine residual nonlinearity and memory effects on the corrected nonlinear component (e.g., the PA to which the pre-distortion is applied). Applying pre-distortion correction factors to the AM/AM and AM/PM error measurement techniques can also help evaluate the efficacy of the pre-distortion correction factors and the pre-distortion unit 110.

In some embodiments, techniques other than pre-distortion correction are used to compensate for the nonlinearity of the PA 104. For example, instead of determining a pre-distortion correction factor, applying the pre-distortion correction factor to the input signal, and analyzing the measured PA output signal 114, the signal analyzer unit 108 might apply a filter to measured PA output signal 114 that filters the distortion from the signal. Thus, some embodiments might not include a pre-distortion unit 110.

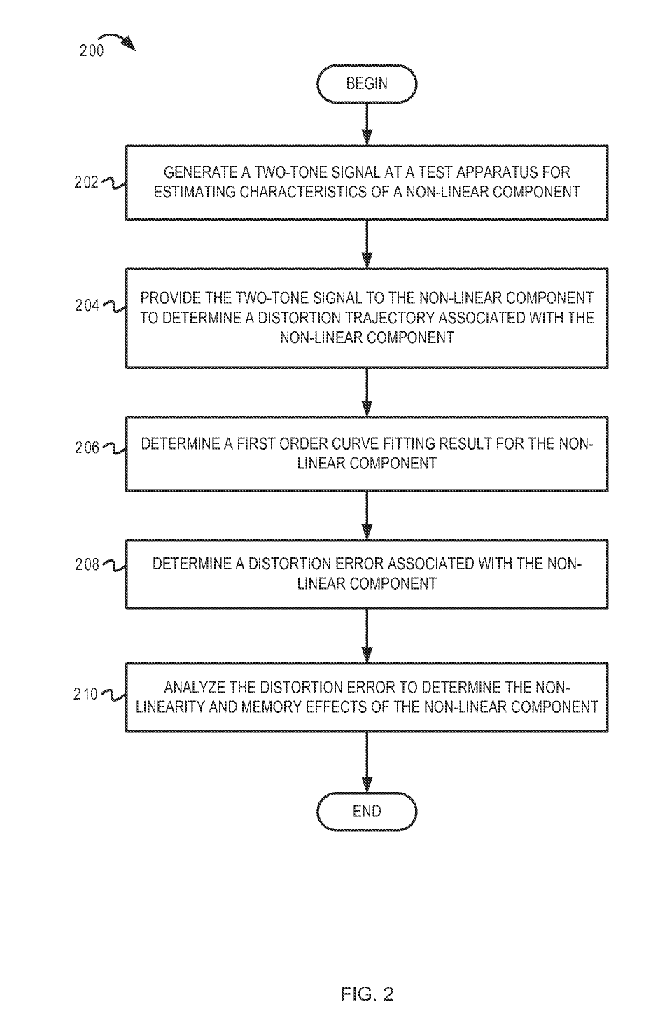

FIG. 2 is a flow diagram (“flow”) 200 illustrating example operations for error measurement using a two-tone signal. The flow 200 begins at block 202.

At block 202, a two-tone signal is generated at a test apparatus for estimating characteristics of a nonlinear component. Referring to the example of FIG. 1, the test apparatus 102 may be configured to evaluate the nonlinearity and memory effects of a nonlinear component, such as a power amplifier, a diode, and an inductor. Similarly, the test apparatus 102 can be configured to evaluate the nonlinearity and memory effects of a system that includes one or more nonlinear components. The signal generation unit 106 can generate the two-tone signal to be used for estimating characteristics of the nonlinear component(s). The flow continues at block 204.

At block 204, the two-tone signal is provided to the nonlinear component to determine a distortion trajectory associated with the nonlinear component. In some embodiments, amplitude distortion (AM/AM) and phase distortion (AM/PM) trajectories associated with the nonlinear component may be determined. For example, to evaluate the nonlinearity and memory effects of the PA 104, the signal generation unit 106 can provide the two-tone signal to the input of the PA 104. The signal analyzer unit 108 can determine a measured PA output signal. The signal analyzer unit 108 can synchronize and compare the measured PA output signal and the input two-tone signal to determine the amplitude distortion (AM/AM) and phase distortion (AM/PM) trajectories. The flow continues at block 206.

At block 206, a first order curve fitting result is determined for the nonlinear component. As described above with reference to FIG. 1, the signal analyzer unit 108 can determine a linear coefficient k using the measured PA output signal (y) and the input two-tone signal (x). The signal analyzer unit 108 can then determine the first order curve fitting result in accordance with Eq. 2. The flow continues at block 208.

At block 208, a distortion error associated with the nonlinear component is determined. For example, an instantaneous amplitude distortion (AM/AM) error and an instantaneous phase distortion (AM/PM) error associated with the nonlinear component may be determined. As described above with reference to FIG. 1, the signal analyzer unit 108 can compare the amplitude distortion and phase distortion trajectories to the first order curve fitting result. The amplitude distortion error and the phase distortion error can be determined using Eq. 3. The flow continues at block 210.

At block 210, the distortion error is analyzed to determine the nonlinearity and memory effects of the nonlinear component. For example, the amplitude distortion error and the phase distortion error can be used to quantify memory effects of the PA 104. The signal analyzer unit 108 may determine peak-to-peak error measurements, average (or mean) error measurements, the variance of error measurements, maximum and/or minimum error measurements, or other suitable time domain representations of the distortion error to quantify the PA 104 and to determine whether the nonlinearity or the memory effects will affect the communication performance of the network device where the PA 104 will be deployed. In one example, the average error measurements may be compared against an error threshold to determine whether the nonlinearity of the PA 104 is at an acceptable level. As another example, a peak-to-peak error measurement may be compared against an error threshold to determine whether the memory effects of the PA 104 are at an acceptable level. In some embodiments, the distortion error may also be used to determine correction factors to compensate for the nonlinearity and memory effects. For example, pre-distortion correction factors for applying to a signal scheduled for transmission may be determined using the inversed AM/AM and AM/PM trajectories and the corresponding distortion error. In some embodiments, the distortion error may also be used to determine whether and how to redesign (or vary the design of) the PA 104. From block 210, the flow ends.

In some embodiments, pre-distortion correction factors may be applied to the two-tone signal and the resultant pre-distorted two-tone signal may be provided to the PA 104. As depicted in FIG. 1, the signal generation unit 106 may generate the two-tone signal as described above in Eq. 1. The signal generation unit 106 may provide the two-tone signal to the pre-distortion unit 110. The pre-distortion unit 110 may determine pre-distortion correction factors to compensate for the PA nonlinearity and/or memory effects in the digital domain. The pre-distortion correction factors may be tailored to the PA 104 and may be determined using various suitable techniques (e.g., loopback techniques). The resultant pre-distorted two-tone signal may be provided from the pre-distortion unit 110 to the PA 104. The signal generation unit 108 can determine the measured PA output signal at the output of the PA 104. The signal generation unit 108 can synchronize and compare the measured PA output signal with the two-tone signal at the output of the signal generation unit 106 (that has not been pre-distorted). The signal generation unit 108 can execute similar operations described above in blocks 206-210 to quantify the errors generated by the nonlinearity and memory effects of the PA 104.

Executing the AM/AM and AM/PM error measurement techniques using the pre-distorted two-tone signal can help determine the efficacy of the pre-distortion correction factors. For example, the pre-distortion correction factors may be selected to minimize nonlinearity and/or memory effects. The AM/AM and AM/PM error measurement techniques can be executed to estimate the residual nonlinearity and memory effects at the output of the PA 104. This can help determine how much of the nonlinearity and memory effects of the PA 104 can be corrected using a particular set of pre-distortion correction factors. If the residual nonlinearity and memory effects meet a predetermined threshold, it may be determined that the selected pre-distortion correction factors can help achieve a desired communication performance.

In some embodiments, the pre-distortion correction factors may compensate for the nonlinearity of the PA 104 and may not compensate for the memory effects of the PA 104. In these embodiments, the pre-distortion correction factor may be applied to the two-tone signal to minimize the nonlinearity effects at the PA 104. The result of the AM/AM and AM/PM error measurement techniques may yield a distortion error that represents the memory effects of the PA 104. The distortion error can be further analyzed to further quantify the memory effects of the PA 104. The distortion error can then be used to determine whether and/or how to redesign or tune the PA 104 to minimize the memory effects. Alternatively, in some embodiments, a memory pre-distortion factor may be applied to the two-tone signal to minimize the memory effects at the PA 104. In this embodiment, the result of the AM/AM and AM/PM error measurement techniques may yield a distortion error that represents the nonlinearity of the PA 104. The distortion error can be further analyzed to further quantify and minimize the nonlinearity of the PA 104. Applying the pre-distortion correction factors to the two-tone signal as described above can allow separation and independent analysis of the nonlinearity effects and memory effects.

Consider for example, the components of a signal output from an example power amplifier. The output signal comprises the amplified input signal, nonlinear distortion, and the memory effects (e.g., artifacts in the output signal caused by the memory associated with the power amplifier). Applying the pre-distortion correction factor to the input signal compensates for at least some of the nonlinear distortion, effectively filtering the nonlinear distortion from the output signal. Thus, even if residual nonlinear distortion remains in the output signal, it is generally not significant enough to impact the output signal. Thus, it can be assumed that the distortion error measurements of the output signal, after correcting the input signal, is generally representative of the memory effects.

The techniques described above can be used to find various operating parameters for the power amplifier. For example, the process of determining the memory effect of the power amplifier can be repeated for various bias values and various tone spacings. By determining which bias value results in the lowest memory effects, the optimal (or most optimal of a set of bias values) can be determined. Consider the following table of example metrics for a particular power amplifier:

TABLE 1

| | | | |
|---|---|---|---|
| PA Bias Setting | Bias 1 | Bias 2 | Bias 3 |

| Average Power (dBm) | | 20 | 20 | 20 |
|---|---|---|---|---|
| EVM (dB) | No DPD | −30 | −31 | −30.2 |
| | Memory- | −35 | −39 | −41 |
| | less DPD | | | |
| Normalized | 5.5 MHz | 0.01 | 0.005 | 0.0075 |
| Max AM/AM | 10 MHz | 0.03 | 0.02 | 0.021 |
| Peak Error | 10.5 MHz | 0.03 | 0.02 | 0.015 |
| at Particular | 15.5 MHz | 0.04 | 0.025 | 0.017 |
| Two-Tone | 20.5 MHz | 0.045 | 0.035 | 0.030 |
| Spacing | | | | |

Table 1 depicts example quantified memory effects for various settings of a power amplifier. In particular, a technique similar to that described above is applied to the power amplifier when applying one of three different bias levels. The particular measurement used to quantify the distortion error measurement into a “memory effect value” is the peak error of a normalized AM/AM for various two-tone spacings. For example, in one instance, the memory effect value is determined for the power amplifier with the bias value set to “bias 1” and the tone spacing of the two-tone signal set to 10 MHz. The resulting memory effect value is 0.03. In one instance, the memory effect value is determined for the power amplifier at the same bias value (“bias 1”), but with the tone spacing of the two-tone signal set to 20.5 MHz. The resulting memory effect value is 0.045. Similarly, the bias values are varied. For example, the memory effect value when the tone spacing of the two-tone signal is 20.5 MHz and the bias value is “bias 1” is 0.045. The memory effect value when the tone spacing of the two-tone signal remains at 20.5 MHz but the bias value is changed to “bias 2”, however, is 0.035.

These resulting memory effect values can be used to compare the various operating parameters of the power amplifier. For example, Table 1 demonstrates that for most two-tone spacings, “bias 3” provides lower memory effects than “bias 1” and “bias 2”. Further, as described above, the memory effect values can be compared to thresholds to determine whether the power amplifier provides low enough memory effect values to meet particular design standards. For example, if the maximum memory effect value is 0.04, the power amplifier memory effect value at a 20.5 MHz tone spacing results in more distortion error than allowable.

The specific tone spacing(s) used can vary between applications. For example, if the PA being tested is used for a narrowband communications system, the tone spacing(s) selected for the test will generally be narrower than for a wideband communications system. Similarly, if the PA being tested is used for a wideband communications system, the tone spacing(s) selected for the test will generally be wider than for a narrowband communications system. More particularly, consider a particular communications system operates that uses 20 MHz channels. The particular tone spacing(s) selected to test a particular 20 MHz channel will typically be selected such that they fall within the 20 MHz range of the channel. Thus, if the test includes multiple tone spacings, the tone spacings might be 1 MHz, 2 MHz, 5 MHz, 10 MHz, and 20 MHz.

In some embodiments, the AM/AM and AM/PM error measurement techniques using a pre-distorted two-tone signal can be used to select a set of pre-distortion correction factors. For example, for each set of pre-distortion correction factors, the AM/AM and AM/PM error measurement techniques using a two-tone signal can be executed and corresponding residual nonlinearity and memory effects can be determined. The set of pre-distortion correction factors that are associated with the smallest residual nonlinearity and memory effects may be selected and applied to the PA 104 after the PA 104 is deployed in a non-test environment. Thus, quantification of the memory effect associated with PA 104 can be further applied to quantify the effectiveness of particular pre-distortion correction factors.

Distortion error may depend on the bias applied to the PA 104 (e.g., depending on the operating point or operating region of the PA 104). For example, when the bias is high, the error spread may be low; and when the bias is low, the error spread may be high. In other words, a higher bias setting may result in a smaller memory (e.g., less prominent memory effects) of the PA 104. Therefore, the two-tone error estimation techniques described above may be used to determine an appropriate bias setting for the PA 104.

The techniques described above are not limited to a single nonlinear component, but can be applied to nonlinear systems that include one or more nonlinear components used in conjunction other components (nonlinear or linear). Thus, for example, the distortion and the distortion error can be determined by providing an input signal to and measuring the output of the nonlinear system, as described above for an individual PA. Similarly, a pre-distortion correction factor can be applied to the input signal and the memory effect determined for the nonlinear system. It should be noted that while, for clarity, the term “system” is used to describe a group of nonlinear components that function together, a nonlinear “component” can comprise a combination of linear and nonlinear components as well.

It should be understood that FIGS. 1-3 are examples meant to aid in understanding embodiments and should not be used to limit embodiments or limit scope of the claims. Embodiments may comprise additional components, different components, and/or may perform additional operations, fewer operations, operations in a different order, operations in parallel, and some operations differently. For example, although error measurement techniques described herein can be performed using a two-tone sinusoidal signal, embodiments are not so limited. In other embodiments, the error measurement techniques can be executed using a multi-tone signal (e.g., a three-tone signal) that has any suitable waveform type (e.g., a triangular waveform). Although examples describe a two-tone error estimation technique being executed to quantify the characteristics of a power amplifier, embodiments are not so limited. In other embodiments, the two-tone error estimation technique may be used to quantify the characteristics of other suitable nonlinear memory components and/or nonlinear memory systems. In some embodiments, a nonlinear memory system may include one or more nonlinear memory components.

As will be appreciated by one skilled in the art, embodiments of the present subject matter may be embodied as a system, method, or program code/instructions embodied in one or more machine-readable media. Accordingly, embodiments may take the form of a hardware embodiment, a software embodiment (including firmware, resident software, micro-code, etc.) or an embodiment combining software and hardware embodiments that may all generally be referred to herein as a “circuit,” “module” or “system.”

Any combination of one or more non-transitory machine readable medium(s) may be utilized. Non-transitory machine-readable media comprise all machine-readable media, with the sole exception being a transitory, propagating signal. The non-transitory machine readable medium may be a machine readable storage medium. A machine readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the machine readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a machine readable storage medium may be any tangible medium that can contain, or store a program for use by or in connection with an instruction execution system, apparatus, or device.

Program instructions/code embodied on a machine readable medium for carrying out operations for embodiments of the subject matter may be written in any combination of one or more programming languages, including an object oriented programming language such as Java, Smalltalk, C++ or the like and conventional procedural programming languages, such as the “C” programming language or similar programming languages. The program code may execute entirely on a single machine or may execute across multiple machines.

Embodiments of the subject matter are described with reference to flowchart illustrations and/or block diagrams of methods, apparatus (systems) and program instructions according to embodiments of the present subject matter. It will be understood that each block of the flowchart illustrations and/or block diagrams, and combinations of blocks in the flowchart illustrations and/or block diagrams, can be implemented by program instructions. These program instructions may be provided to a processor of a general purpose computer, special purpose computer, or other programmable apparatus to produce a machine, such that the instructions, which execute via the processor of the computer or other programmable apparatus, create means for implementing the functions/acts specified in the flowchart and/or block diagram block or blocks.

These program instructions may also be stored in a machine readable medium that can direct any of a variety of machines (e.g., apparatus, device, etc.) to function in a particular manner, such that the instructions stored in the machine readable medium produce an article of manufacture including instructions which implement the function/act specified in the flowchart and/or block diagram block or blocks.

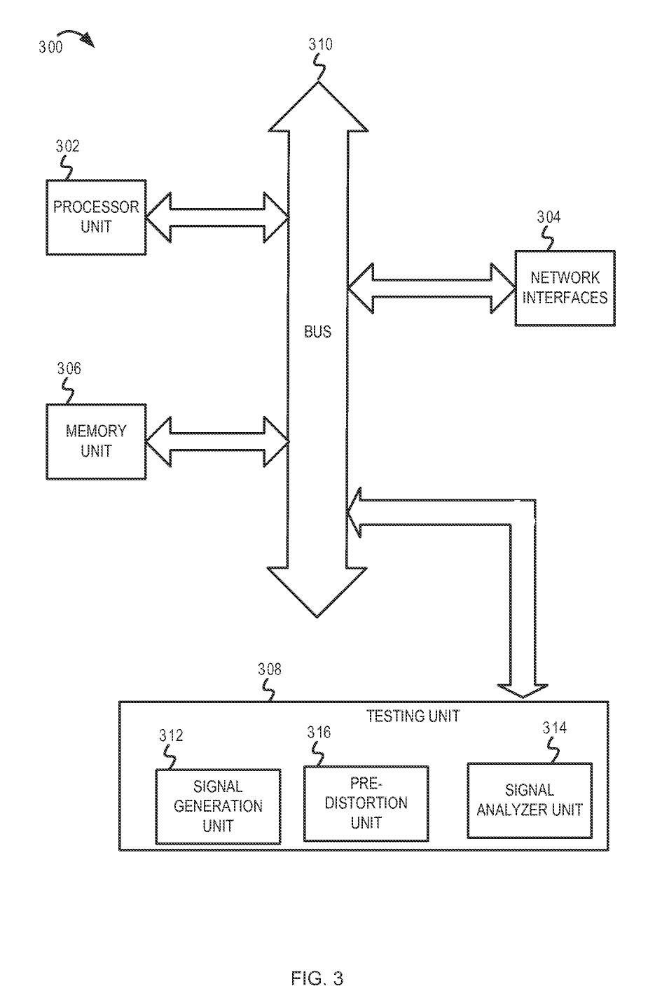

FIG. 3 is a block diagram of an embodiment of an electronic device 300 including a mechanism for two-tone error estimation of a nonlinear component. In some implementations, the electronic device 300 may be a test apparatus that is configured to characterize the nonlinearity and memory effects of a nonlinear memory component as the device under test (DUT). The device under test may be a power amplifier, a nonlinear memory component, or a nonlinear memory system that includes one or more nonlinear memory components. In some embodiments, the device under test may be deployed in various types of communication devices and systems, such as a desktop computer, laptop computer, a tablet computer, a mobile device, a smart appliance, a remote control, a gaming console, a television, a set top box, a media player, or another electronic device with communication capabilities. For example, the power amplifier may be deployed in a WLAN device or another network device that implements wideband communication protocols. The electronic device 300 includes a processor unit 302 (possibly including multiple processors, multiple cores, multiple nodes, and/or implementing multi-threading, etc.). The electronic device 300 includes a memory unit 306. The memory unit 306 may be system memory (e.g., one or more of cache, SRAM, DRAM, zero capacitor RAM, Twin Transistor RAM, eDRAM, EDO RAM, DDR RAM, EEPROM, NRAM, RRAM, SONOS, PRAM, etc.) or any one or more of the above already described possible realizations of non-transitory machine-readable storage media. The electronic device 300 also includes a bus 310 (e.g., PCI, ISA, PCI-Express, HyperTransport®, InfiniBand®, NuBus, AHB, AXI, etc.). The electronic device 300 also includes a network interface 304 that include a wireless network interface (e.g., a WLAN interface, a Bluetooth® interface, a WiMAX interface, a ZigBee® interface, a Wireless USB interface, etc.) and/or a wired network interface (e.g., a PLC interface, an Ethernet interface, etc.). In some embodiments, the electronic device 300 can execute an IEEE Std. 1905.1 protocol for implementing hybrid communication functionality.

The electronic device 300 also includes a testing unit 308. The testing unit 308 includes a signal generation unit 312, a signal analyzer unit 314, and a pre-distortion unit 316. The electronic device 300 (e.g., the test apparatus) may be coupled with a nonlinear component or system (e.g., a power amplifier). As described above in FIGS. 1 and 2, the testing unit 308 can use a two-tone signal in AM/AM and AM/PM error measurement techniques to characterize the nonlinear component.

Any one of these functionalities may be partially (or entirely) implemented in hardware and/or on the processor unit 302. For example, the functionality may be implemented with an application specific integrated circuit, in logic implemented in the processor unit 302, in a co-processor on a peripheral device or card, etc. In some embodiments, the testing unit 308 can each be implemented on a system-on-a-chip (SoC), an application specific integrated circuit (ASIC), or another suitable integrated circuit to enable communications of the electronic device 300. In some embodiments, the testing unit 308 may include additional processors and memory, and may be implemented in one or more integrated circuits on one or more circuit boards of the electronic device 300. Further, realizations may include fewer or additional components not illustrated in FIG. 3 (e.g., video cards, audio cards, additional network interfaces, peripheral devices, etc.). For example, in addition to the processor unit 302 coupled with the bus 310, the testing unit 308 may include at least one additional processor unit. As another example, although illustrated as being coupled to the bus 310, the memory unit 306 may be coupled to the processor unit 302.

While the embodiments are described with reference to various implementations and exploitations, it will be understood that these embodiments are illustrative and that the scope of the present subject matter is not limited to them. In general, techniques for quantifying nonlinearity and/or a memory effect of a component as described herein may be implemented with facilities consistent with any hardware system or hardware systems. Many variations, modifications, additions, and improvements are possible.

Plural instances may be provided for components, operations, or structures described herein as a single instance. Finally, boundaries between various components, operations, and data stores are somewhat arbitrary, and particular operations are illustrated in the context of specific illustrative configurations. Other allocations of functionality are envisioned and may fall within the scope of the present subject matter. In general, structures and functionality presented as separate components in the exemplary configurations may be implemented as a combined structure or component. Similarly, structures and functionality presented as a single component may be implemented as separate components. These and other variations, modifications, additions, and improvements may fall within the scope of the present subject matter.

What is claimed is:

1. A method for quantifying memory effects of electronic components, the method comprising:
transmitting a first input signal to a component;
determining a first distortion associated with the component based, at least in part, on a first output signal generated by the component in response to the first input signal;
determining a first distortion error measurement associated with the component based, at least in part, on the first distortion and the first output signal; and
quantifying a first memory effect associated with the component based, at least in part, on the first distortion error measurement.

2. The method of claim 1, wherein determining the first distortion comprises determining at least one of an amplitude distortion trajectory and a phase distortion trajectory associated with the component.

3. The method of claim 1, wherein determining the first distortion comprises:
synchronizing the first output signal and the first input signal; and
comparing the synchronized first output signal and the first input signal to determine the first distortion associated with the component.

4. The method of claim 1, wherein determining the first distortion error measurement comprises:
determining a linear coefficient based, at least in part, on the first output signal and the first input signal;
determining a curve fitting approximation for the component based, at least in part, on the linear coefficient and the first input signal; and
determining the first distortion error measurement based, at least in part, on comparing the curve fitting approximation and the first output signal.

5. The method of claim 4, wherein determining the first distortion error measurement based, at least in part, on comparing the curve fitting approximation and the first output signal comprises:
determining a difference between the first output signal and the curve fitting approximation.

6. The method of claim 1 further comprising:
determining a pre-distortion correction factor based, at least in part, on the first distortion error measurement; and
generating a second input signal based, at least in part, on the pre-distortion correction factor;
wherein quantifying the first memory effect comprises,
transmitting the second input signal to the component; and
analyzing a second output signal generated by the component in response to the second input signal.

7. The method of claim 6, wherein analyzing the second output signal comprises:
determining a second distortion associated with the component based, at least in part, on the second output signal;
determining a second distortion error measurement associated with the component based, at least in part, on the second distortion and the second output signal generated by the component, wherein the second distortion error measurement comprises the first memory effect; and
determining a memory effect value based, at least in part, on the second distortion error measurement.

8. The method of claim 7, wherein the memory effect value is based, at least in part, on at least one member selected from a group consisting of a peak-to-peak measurement associated with the second distortion error measurement, an average associated with the second distortion error measurement, a maximum associated with the second distortion error measurement, a minimum associated with the second distortion error measurement, and a variance associated with the second distortion error measurement.

9. The method of claim 7, wherein the second distortion error measurement is normalized such that the ratio of the second distortion error measurement to the second input signal is unity gain.

10. The method of claim 1, wherein the first memory effect influences the first output signal based on a history of at least one of the first input signal and the first output signal.

11. The method of claim 1, wherein the first input signal comprises a first signal component and a second signal component, the method further comprising:
synchronizing the first signal component and the second signal component.

12. The method of claim 1, wherein the component is a nonlinear component.

13. The method of claim 1, wherein the component is at least one member selected from a group consisting of a power amplifier, a diode, and an inductor.

14. The method of claim 13, wherein quantifying the first memory effect comprises quantifying the first memory effect when a first bias is applied to the component, the method further comprising:
quantifying a second memory effect when a second bias is applied to the component; and
determining that the second memory effect is less than the first memory effect.

15. The method of claim 1 wherein the first input signal is a two-tone signal with a first frequency spacing, wherein the method further comprises:
transmitting a second input signal to the component, wherein the second input signal comprises a two-tone signal with a second frequency spacing;
determining a second distortion associated with the component based, at least in part, on a second output signal generated by the component in response to the second input signal;
determining a second distortion error measurement associated with the component based, at least in part, on the second distortion and the second output signal generated by the component; and
quantifying a second memory effect associated with the component based, at least in part, on the second distortion error measurement; and
determining that the first memory effect is less than a threshold and that the second memory effect is greater than the threshold.

16. A non-transitory machine-readable storage medium having instructions stored therein, the instructions to:
transmit a first input signal to a component;
determine a first distortion associated with the component based, at least in part, on a first output signal generated by the component in response to the first input signal;
determine a first distortion error measurement associated with the component based, at least in part, on the first distortion and the first output signal; and
quantify a first memory effect associated with the component based, at least in part, on the first distortion error measurement.

17. The non-transitory machine-readable storage medium of claim 16 further having stored therein instructions to:
determine a pre-distortion correction factor based, at least in part, on the first distortion error measurement;
generate a second input signal based, at least in part, on the pre-distortion factor;
wherein the instructions to quantify the first memory effect comprise instructions to:
transmit the second input signal to the component; and
analyze a second output signal generated by the component in response to the second input signal.

18. The non-transitory machine-readable storage medium of claim 17, wherein the instructions to analyze the second output signal comprise instructions to:
determine a second distortion associated with the component based, at least in part, on the second output signal;
determine a second distortion error measurement associated with the component based, at least in part, on the second distortion and the second output signal, wherein the second distortion error measurement comprises the first memory effect; and
determine a memory effect value based, at least in part, on the second distortion error measurement.

19. The non-transitory machine-readable storage medium of claim 16 further having stored therein instructions to synchronize a first signal component of the first input signal with a second signal component of the first input signal.

20. The non-transitory machine-readable storage medium of claim 17, wherein the instructions to determine a second distortion error measurement comprise instructions to normalize the second distortion error measurement such that the ratio of the second distortion error measurement to the second input signal is unity gain

21. A device comprising:
a signal generation unit configured to generate a first input signal; and
a machine-readable storage medium having instructions stored therein, the instructions executable to cause the device to,
cause the signal generation unit to transmit the first input signal to a nonlinear component;
determine a first distortion associated with the nonlinear component based, at least in part, on a first output signal generated by the nonlinear component in response to the first input signal;
determine a first distortion error measurement associated with the nonlinear component based, at least in part, on the first distortion and the first output signal; and
quantify a first memory effect associated with the nonlinear component based, at least in part, on the first distortion error measurement.

22. The device of claim 21, wherein the machine-readable storage medium further has stored therein instructions executable to cause the device to:
determine a pre-distortion correction factor based, at least in part, on the first distortion error measurement;
wherein the instructions that cause the device to quantify the first memory effect comprise instructions that cause the device to:
cause the signal generation unit to generate a second input signal based, at least in part, on the pre-distortion factor and transmit the second input signal to the nonlinear component; and
analyze a second output signal generated by the nonlinear component in response to the second input signal.

23. The device of claim 22, wherein the instructions that cause the device to analyze the second output signal comprise instructions that cause the device to:
determine a second distortion associated with the nonlinear component based, at least in part, on the second output signal;
determine a second distortion error measurement associated with the nonlinear component based, at least in part, on the second distortion and the second output signal, wherein the second distortion error measurement comprises the first memory effect; and
determine a memory effect value based, at least in part, on the second distortion error measurement.

24. The device of claim 21 further comprising the nonlinear component.

25. The device of claim 21, wherein the machine-readable storage medium further has stored therein instructions that cause the signal generation unit to transmit the first input signal to the nonlinear component in response to determining that the nonlinear component has been coupled with the device.

26. A device comprising:
a signal generation unit configured to generate a first input signal and a second input signal; and
a machine-readable storage medium having instructions stored therein, the instructions executable to cause the device to,
cause the first input signal to be transmitted to a nonlinear component;
detect a first output signal generated by the nonlinear component in response to the first input signal, wherein the first output signal comprises a nonlinear distortion component and a memory effect component;
cause the second input signal to be transmitted to the nonlinear component, wherein the second input signal comprises the first input signal modified by a pre-distortion correction factor;
detect a second output signal generated by the nonlinear component in response to the second input signal, wherein the second output signal comprises a residual nonlinear distortion component and the memory effects component;
determine first distortion error values based, at least in part, on the second output signal, wherein the first distortion error values indicate the memory effects component; and
determine a memory effect value based, at least in part, on the first distortion error values.

27. The device of claim 26, wherein the machine-readable medium further has instructions that cause the device to:
determine a distortion trajectory based, at least in part, on the first output signal;
determine second distortion error values based, at least in part, on the distortion trajectory and the first input signal;
determine the pre-distortion correction factor based, at least in part, on the second distortion error values; and
combine the first input signal with the pre-distortion correction factor, wherein the pre-distortion correction factor at least partially compensates for the nonlinear distortion.

28. The device of claim 26, wherein the instructions that cause the device to determine a memory effect value comprise instructions that cause the device to:
apply at least one member selected from a group consisting of a peak-to-peak measurement, and average measurement, a maximum measurement, a minimum measurement, and a variance measurement to the first distortion error values.

29. The device of claim 26, wherein the device further comprises the nonlinear component.

30. The device of claim 26, wherein the nonlinear component comprises at least one member selected from a group consisting of a power amplifier, a diode, and an inductor.
